(19) United States
(12) Patent Application Publication
(10) Pub. No.: US 2009/0047764 A1
(43) Pub. Date: Feb. 19, 2009

(54) NON-VOLATILE MEMORY AND MANUFACTURING METHOD THEREOF

(75) Inventors: Wei-Ming Liao, Taipei City (TW); Ming-Cheng Chang, Taipei County (TW); Chien-Chang Huang, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NANYA TECHNOLOGY CORPORATION, Taoyuan (TW)

(21) Appl. No.: 11/953,076

(22) Filed: Dec. 10, 2007

(30) Foreign Application Priority Data
Aug. 13, 2007 (TW) 96129849

(51) Int. Cl. H01L 21/336

(52) U.S. Cl. 438/261; 257/E21.409

(57) ABSTRACT

A non-volatile memory having a gate structure and a source/drain region is provided. The gate structure is disposed on a substrate. The gate structure includes a pair of floating gates, tunneling dielectric layers, a control gate and an inter-gate dielectric layer. The floating gates are disposed on the substrate. Each tunneling dielectric layer is disposed between each floating gate and the substrate. The control gate is disposed on the substrate between the pair of the floating gates and covers a top surface and sidewalls of each floating gate. The inter-gate dielectric layer is disposed between the control gate and each of the floating gates, disposed between the control gate and each of the tunneling dielectric layers, and disposed between the control gate and the substrate. The source/drain region is disposed in the substrate at respective sides of the gate structure.

### CROSS-REFERENCE TO RELATED APPLICATION

This application claims the priority benefit of Taiwan application serial no. 96129849, filed on Aug. 13, 2007. The entirety of the above-mentioned patent application is hereby incorporated by reference herein and made a part of this specification.

### BACKGROUND OF THE INVENTION

1. Field of the Invention

The present invention relates to a memory and a manufacturing method thereof. More particularly, the present invention relates to a non-volatile memory and a manufacturing method thereof.

2. Description of Related Art

A non-volatile memory allows multiple data writing, reading and erasing operations. The stored data in the non-volatile memory will still be retained even after power to a device using the non-volatile memory is off. With these advantages, the non-volatile memory has become one of the most widely adopted memories for personal computers and electronic equipment. However, as semiconductor devices are continuously miniaturized and line widths of the devices are reduced, dimensions of the memories are also decreased, such that a coupling ratio between a control gate and a floating gate in the non-volatile memory drops significantly.

Thus, in most cases, an overlapping area between the control gate and the floating gate is increased to raise the coupling ratio between the control gate and the floating gate.

FIG. 1 is a schematic cross-sectional view of a conventional non-volatile memory. Referring to FIG.1, the non-volatile memory includes a substrate 100, a gate structure 102, and a source/drain region 104. The gate structure 102 is disposed on the substrate 100. The source/drain region 104 is disposed in the substrate 100 on respective sides of the gate structure 102. The gate structure 102 is constituted by a I-shaped control gate 106, a pair of floating gates 108, tunneling dielectric layers 110, and an inter-gate dielectric layer 112. The floating gates 108 are disposed on the substrate 100. The tunneling dielectric layers 110 are disposed between the floating gates 108 and the substrate 100. The control gate 106 is disposed between the two floating gates 108 and engages a side surface of each of the floating gates 108 (there is no mutual relationship between the control gate and the floating gate because the inter-gate dielectric layer 112 is situated therebetween). The inter-gate dielectric layer 112 is disposed between the control gate 106 and each of the floating gates 108, and disposed between the control gate 106 and each of the tunneling dielectric layers 110. Besides, the inter-gate dielectric layer 112 is disposed between the control gate 106 and the substrate 100.

The I-shaped control gate 106 as shown in FIG. 1 can only engage with a side wall of each of the floating gates 108, such that the coupling ratio between the control gate 106 and the floating gates 108 is limited.

Nevertheless, in the aforesaid non-volatile memory, even though the disposition of the control gate is utilized, the coupling ratio cannot be substantially improved to meet the increasingly advanced requirements.

### SUMMARY OF THE INVENTION

In view of the foregoing shortcomings, the present invention is directed to a manufacturing method of a non-volatile memory to solve the problem incurred by the coupling ratio between the control gate and floating gates. The manufacturing method is able to increase an overlapping area between the control gate and the floating gate via an improved three-dimensional manufacturing process.

The method of the present invention provides an improved manufacturing method to allow the control gate to engage with a top face of each of the two floating gates such that the coupling ratio therebetween is increased.

The present invention provides a manufacturing method of a non-volatile memory. In the method, a first dielectric layer and a first conductive layer are formed sequentially on a substrate. Thereafter, an isolation structure is formed in the first conductive layer, the first dielectric layer and the substrate, so as to define a plurality of bar-shaped conductive layers and a plurality of bar-shaped dielectric layers in a column direction of the substrate. Next, a portion of the isolation structure is removed to expose at least a portion of sidewalls of each of the bar-shaped conductive layers. After that, each of the bar-shaped conductive layers and each of the bar-shaped dielectric layers are patterned to form a plurality of gate structures. A second dielectric layer is then conformally formed on the substrate. Afterwards, a second conductive layer is formed on the second dielectric layer. Next, the second conductive layer is patterned to form a plurality of third conductive layers. Here, each of the third conductive layers is disposed on the second dielectric layer between the two gate structures in the column direction, and each of the third conductive layers covers at least a portion of each of the sidewalls of each of the gate structures. Thereafter, a source/drain region is formed in the substrate between the third conductive layers in the column direction. Eternally, a third dielectric layer is formed between the third conductive layers.

According to an embodiment of the present invention, the step of removing a portion of the isolation structure includes performing an etching back process, for example.

According to an embodiment of the present invention, the isolation structure is formed by firstly forming a trench in the first conductive layer, the first dielectric layer and the substrate, for example. Next, a dielectric material layer is formed on the substrate. Thereafter, a planarization process is performed to remove a portion of the dielectric material layer until the first conductive layer is exposed.

According to an embodiment of the present invention, the step of forming the gate structures includes forming a patterned photoresist layer on the isolation structure and on a portion of each of the bar-shaped conductive layers. Next, a portion of each of the bar-shaped conductive layers and a portion of each of the bar-shaped dielectric layers are removed with use of the patterned photoresist layer as a mask. Finally, the patterned photoresist layer is removed.

According to an embodiment of the present invention, the second dielectric layer is formed by performing a chemical vapor deposition (CVD) process, for example.

According to an embodiment of the present invention, the second dielectric layer is an oxide layer/nitride layer/oxide layer structure, for example.

According to an embodiment of the present invention, the step of forming the third conductive layers includes forming a patterned photoresist layer at first. The patterned photoresist layer covers the second conductive layer above and between two of the gate structures in the column direction, and covers a portion of the second conductive layer surrounding each of the gate structures. Next, a portion of the second conductive layer is removed with use of the patterned photoresist layer as a mask. Finally, the patterned photoresist layer is removed.

According to an embodiment of the present invention, after the second conductive layer is formed but before the second conductive layer is patterned, the second conductive layer can be further planarized.

The present invention further provides a non-volatile memory including a gate structure and a source/drain region. The gate structure is disposed on a substrate. The gate structure includes a pair of floating gates, tunneling dielectric layers, a control gate and an inter-gate dielectric layer. The floating gates are disposed on the substrate. Each of the tunneling dielectric layers is disposed between each floating gate and the substrate. The control gate is disposed on the substrate between the pair of the floating gates. Besides, the control gate covers a top surface of each of the floating gates and surrounds sidewalls of each of the floating gates. The inter-gate dielectric layer is disposed between the control gate and each of the floating gates, disposed between the control gate and each of the tunneling dielectric layers, and disposed between the control gate and the substrate. The source/drain region is disposed in the substrate at respective sides of the gate structure.

According to another embodiment of the present invention, the control gate completely covers each of the floating gates, for example.

According to another embodiment of the present invention, a material of the floating gates is polysilicon, for example.

According to another embodiment of the present invention, a material of the control gate is polysilicon, for example.

According to another embodiment of the present invention, a material of the tunneling dielectric layers is oxide, for example.

According to another embodiment of the present invention, a material of the inter-gate dielectric layer is oxide/nitride/oxide, for example.

In the present invention, a portion of the isolation structure surrounding the floating gates is removed before the control gate is formed. Thus, after the control gate is formed between the floating gates, the control gate not only covers the top surface of each of the floating gates, but also covers at least a portion of each of the sidewalls of each of the floating gates, so as to increase the overlapping area between the control gate and the floating gates. Further, the coupling ratio between the control gate and the floating gates is then improved.

In order to make the aforementioned and other objects, features and advantages of the present invention more comprehensible, several embodiments accompanied with figures are described in detail below.

### BRIEF DESCRIPTION OF THE DRAWINGS

FIG. 1 is a schematic cross-sectional view of a conventional non-volatile memory.

FIGS. 2A through 2F are top views illustrating a process of manufacturing a non-volatile memory according to an embodiment of the present invention.

FIGS. 3A through 3F are cross-sectional views illustrating the process of manufacturing the non-volatile memory along a I-I′ cross-section in FIGS. 2A through 2F.

FIGS. 4A through 4F are cross-sectional views illustrating the process of manufacturing the non-volatile memory along a II-II′ cross-section in FIGS. 2A through 2F.

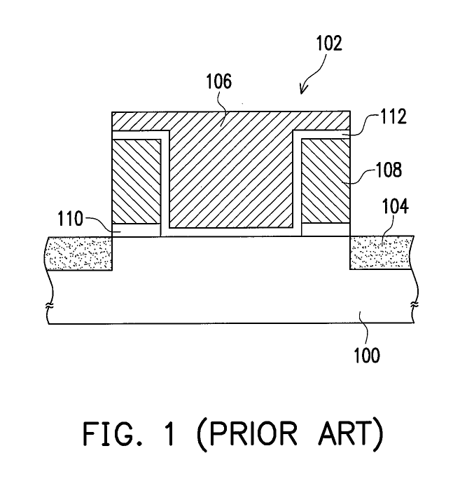

### DESCRIPTION OF EMBODIMENTS

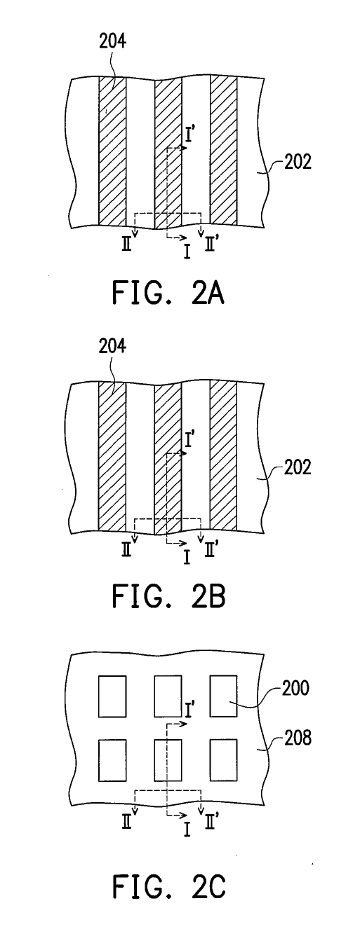

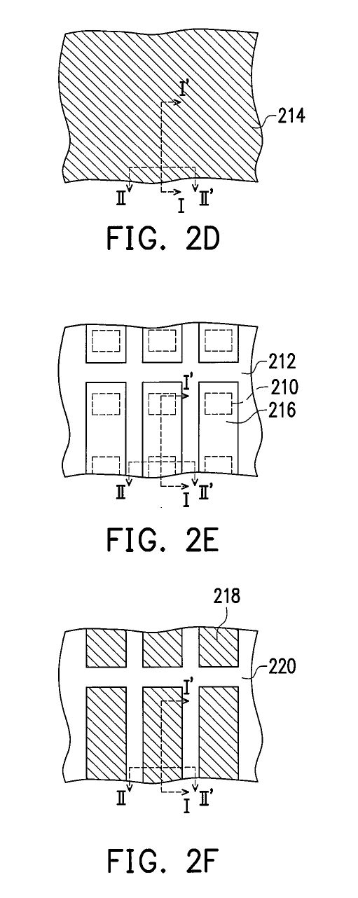

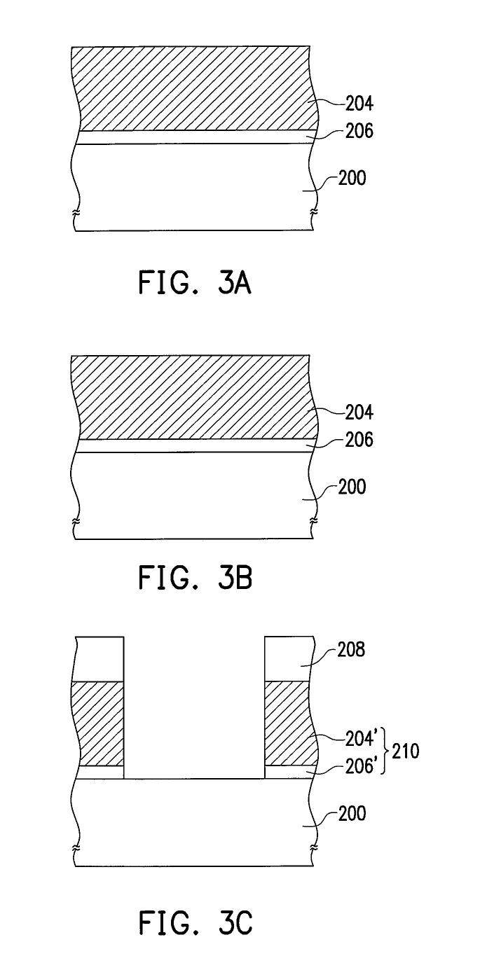

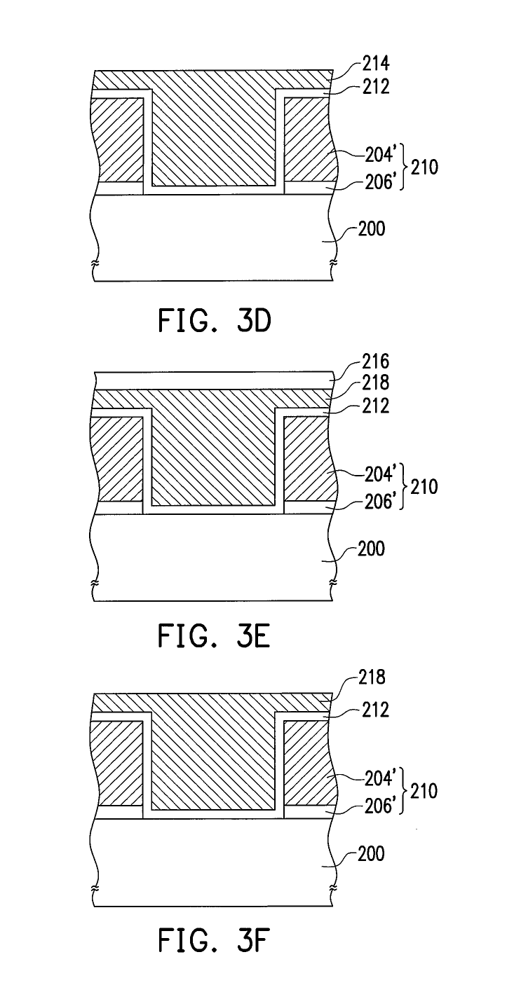

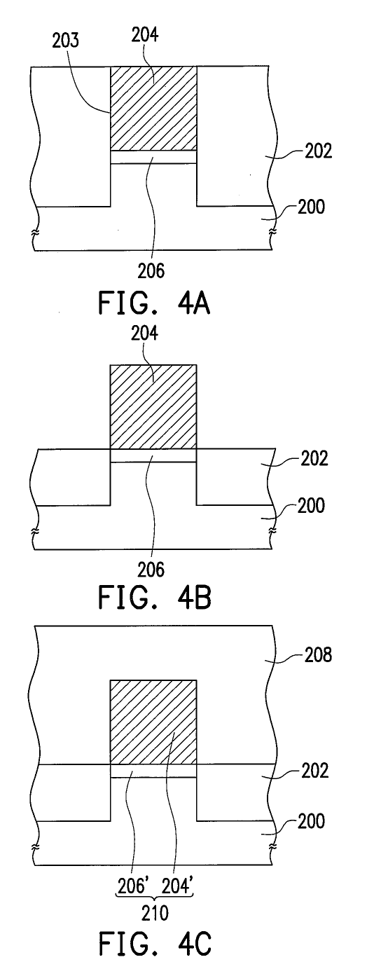

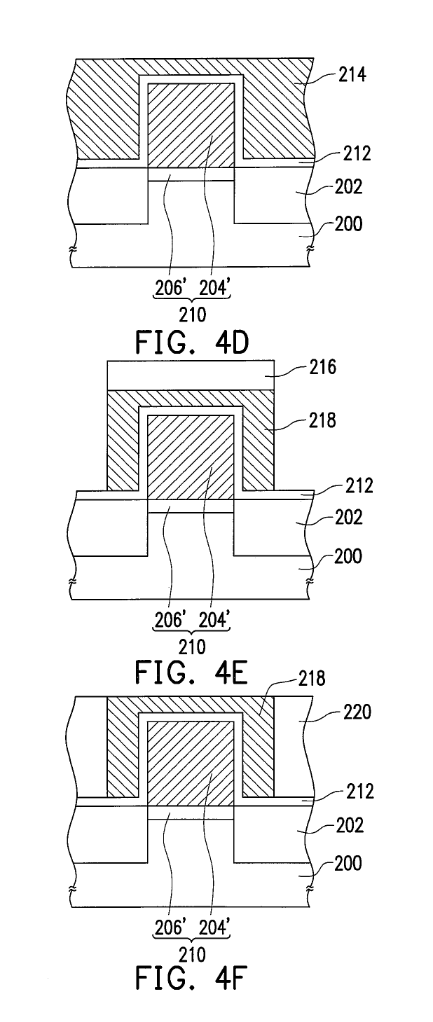

FIGS. 2A through 2F are top views illustrating a process of manufacturing a non-volatile memory according to an embodiment of the present invention. FIGS. 3A through 3F are cross-sectional views illustrating the process of manufacturing the non-volatile memory along a I-I′ cross-section in FIGS. 2A through 2F. FIGS. 4A through 4F are cross-sectional views illustrating the process of manufacturing the non-volatile memory along a II-II′ cross-section in FIGS. 2A through 2F.

First, referring concurrently to FIGS. 2A, 3A and 4A, a substrate 200 is provided. The substrate 200 is, for example, a silicon substrate. Next, a dielectric layer (now shown) and a conductive layer (now shown) are sequentially formed on the substrate 200. A material of the dielectric layer is oxide, for example, and the dielectric layer is formed, for example, by thermal oxidation. A material of the conductive layer is, for example, polysilicon, and the conductive layer is formed by performing a chemical vapor deposition (CVD) process, for example. Thereafter, an isolation structure 202 is formed in the conductive layer, the dielectric layer, and the substrate 200, so as to define a plurality of bar-shaped conductive layers 204 and a plurality of bar-shaped dielectric layers 206 in a column direction of the substrate 200. A material of the isolation structure 202 is high density plasma (HDP) oxide, for example, and the isolation structure 202 is formed by first forming a trench 203 in the conductive layer, the dielectric layer and the substrate 200, for example. Next, an oxide layer (not shown) is formed on the substrate 200. Thereafter, a planarization process is implemented by performing a chemical-mechanical polishing (CMP) step to remove a portion of the oxide layer until the conductive layer is exposed.

After that, referring concurrently to FIGS. 2B, 3B and 4B, a portion of the isolation structure 202 is removed, so as to expose at least a portion of sidewalls of the bar-shaped conductive layers 204. The portion of the isolation structure 202 is removed by performing an etching back process, for example. Note that the exposed sidewalls of the bar-shaped conductive layers 204 are conducive to increase an overlapping area between a control gate and floating gates of the non-volatile memory according to the present invention, so as to improve a coupling ratio therebetween. Besides, the thickness of the removed portion of the isolation structure 202 may be determined upon actual demands for the non-volatile memory. In general, the thickness of the removed isolation structure 202 may completely expose the sidewalls of the bar-shaped conductive layers 204, for example, so as to make said overlapping area to the greatest extent.

Thereafter, as shown in FIGS. 2C, 3C and 4C, a patterned photoresist layer 208 is formed on the substrate 200. The patterned photoresist layer 208 covers the isolation structure 202 and a portion of each of the bar-shaped conductive layers 204 (i.e. an area where the floating gates are to be formed) An anisotropic etching process is then performed with use of the patterned photoresist layer 208 as a mask, so as to remove a portion of each of the bar-shaped conductive layers 204 and a portion of each of the bar-shaped dielectric layers 206. As such, conductive layers 204′ and dielectric layers 206′ are formed, by which stacked gate structures 210 are constructed. In one of the gate structures 210, the conductive layer 204′ and the dielectric layer 206′ serve as the floating gate and the tunneling dielectric layer in the non-volatile memory of the present invention, respectively.

Afterwards, referring concurrently to FIGS. 2D, 3D and 4D, the patterned photoresist layer 208 is removed. Then, a dielectric layer 212 is conformally formed on the substrate 200. The dielectric layer 212 is a composite layer formed by an oxide layer/nitride layer/oxide layer structure, for example. Besides, the dielectric layer 212 is manufactured by, for example, forming a first oxide layer through thermal oxidation. The nitride layer is then formed on the first oxide layer through performing the CVD process. Thereafter, a second oxide layer is formed on the nitride layer through thermal oxidation. However, in other embodiments, the dielectric layer 212 may also be the oxide layer directly formed by performing the CVD process. Then, a conductive layer 214 is formed on the dielectric layer 212. A material of the conductive layer 214 is, for example, polysilicon. Afterwards, the planarization process is performed on the conductive layer 214 through selectively implementing the CMP step.

Referring concurrently to FIGS. 2E, 3E and 4E, a patterned photoresist layer 216 is then formed on the conductive layer 214. The patterned photoresist layer 216 covers the conductive layer 214 above and between two of the gate structures 210 in the column direction, and covers a portion of the conductive layer 214 surrounding each of the gate structures 210. Next, the anisotropic etching process is performed with use of the patterned photoresist layer 216 as the mask to remove the conductive layer 214 uncovered by the patterned photoresist layer 216, such that conductive layers 218 are formed in the column direction. Here, each of the conductive layers 218 is disposed on the dielectric layer 212 between two of the gate structures 210 in the column direction and covers at least a portion of each of the sidewalls of each of the gate structures 210 in the column direction.

It should be mentioned that the conductive layer 218 serves as the control gate of the non-volatile memory in the present invention. The control gate disposed between two of the gate structures 210 not only covers a top surface of each of the gate structures 210, but also covers at least a portion of each of the sidewalls of each of the gate structures 210. Accordingly, the overlapping area between the control gate and the floating gates is increased, and the coupling ratio between the control gate and the floating gate is further improved. Moreover, the overlapping area between the control gate and the floating gate may be changed through adjusting the thickness of the removed portion of the gate structures 202 depicted in FIGS. 2B, 3B and 4B based on the actual demands.

Afterwards, referring concurrently to FIGS. 2F, 3F and 4F, the patterned photoresist layer 216 is removed. Finally, a well known process is subsequently carried out. Namely, a source/drain region (not shown) is formed, and a dielectric layer 220 is formed between the conductive layers 218, so as to complete the fabrication of the non-volatile memory of the present invention.

As exemplified in FIGS. 2F, 3F and 4F, the non-volatile memory of the present invention will be elaborated hereinafter.

Referring concurrently to FIGS. 2F, 3F and 4F, the non-volatile memory of the present invention includes a gate structure and a source/drain region (not shown). The gate structure is disposed on the substrate 200. The gate structure includes a pair of floating gates (the conductive layers 204′), tunneling dielectric layers (the dielectric layers 206′), a control gate (the conductive layer 218) and an inter-gate dielectric layer (the dielectric layer 212). The floating gates are disposed on the substrate 200, and a material of the floating gates is polysilicon, for example. Each of the tunneling dielectric layers is disposed between each of the floating gates and the substrate 200, and a material of the tunneling dielectric layers is oxide, for example. The control gate is disposed on the substrate 200 between the pair of the floating gates. Besides, the control gate covers a top surface of each of the floating gates and surrounds the sidewalls of each of the floating gates. A material of the control gate is polysilicon, for example. In addition, the control gate may completely cover the sidewalls of each of the floating gates, so as to make said overlapping area to the greatest extent. The inter-gate dielectric layer is disposed between the control gate and each of the floating gates, disposed between the control gate and each of the tunneling dielectric layers, and disposed between the control gate and the substrate 200. A material of the inter-gate dielectric layer is, for example, oxide/nitride/oxide. The source/drain region is disposed in the substrate 200 at respective sides of the gate structure.

To be more specific, in the non-volatile memory of the present invention, the control gate disposed between the two floating gates not only engages with a side wall of each of the two floating gates, but also engages with a top face of each of the floating gates. Hence, the overlapping area between the control gate and the floating gates is increased, and the coupling ratio therebetween is further improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A manufacturing method of a non-volatile memory, the method comprising:
forming a first dielectric layer and a first conductive layer on a substrate in sequence;
forming an isolation structure in the first conductive layer, the first dielectric layer and the substrate, so as to define a plurality of bar-shaped conductive layers and a plurality of bar-shaped dielectric layers in a first direction of the substrate;
partially removing the isolation structure to expose at least a portion of sidewalls of each of the bar-shaped conductive layers;
patterning each of the bar-shaped conductive layers and each of the bar-shaped dielectric layers to form a plurality of gate structures;
conformally forming a second dielectric layer on the substrate to blanket each of the gate structures;
providing a second conductive layer in a space between two adjacent gate structures and on the second dielectric layer;
patterning the second conductive layer, wherein each of the second conductive layers covers sidewalls and a top face of each of the gate structures; and
forming a source/drain region in the substrate between the second conductive layers in the first direction.

2. The method of claim 1, wherein the isolation structure removing step comprises performing an etching back process.

3. The method of claim 1, wherein the isolation structure forming step comprises:
forming a trench in the first conductive layer, the first dielectric layer and the substrate;
forming a dielectric material layer on the substrate to fill the trench; and
performing a planarization process to remove a portion of the dielectric material layer to expose the first conductive layer.

4. The method of claim 3, wherein the gate structure forming step comprises:
forming a patterned photoresist layer on the isolation structure and on a portion of each of the bar-shaped conductive layers;
partially removing each of the bar-shaped conductive layers and each of the bar-shaped dielectric layers with use of the patterned photoresist layer as a mask; and
removing the patterned photoresist layer.

5. The method of claim 1, wherein the step of forming the second dielectric layer comprises performing a chemical vapor deposition (CVD) process.

6. The method of claim 1, wherein the second dielectric layer comprises an oxide layer/nitride layer/oxide layer structure.

7. The method of claim 3, wherein the second conductive layer forming step comprises:
forming a patterned photoresist layer to cover the second conductive layer above and between two adjacent gate structures in the first direction;
partially removing the second conductive layer with use of the patterned photoresist layer as a mask; and
removing the patterned photoresist layer.

8. The method of claim 4, wherein the second conductive layer forming step comprises:
forming a patterned photoresist layer to cover the second conductive layer above and between two adjacent gate structures in the first direction;
partially removing the second conductive layer with use of the patterned photoresist layer as a mask; and
removing the patterned photoresist layer.

9. The method of claim 1, further comprising planarizing the second conductive layer after the second conductive layer is formed but before the second conductive layer is patterned.

10. A non-volatile memory, comprising:
a gate structure disposed on a substrate, the gate structure comprising:
a pair of floating gates disposed on the substrate;
tunneling dielectric layers disposed respectively between each of the floating gates and the substrate;
a control gate disposed in a space between the pair of floating gates so as to engage with sidewalls of each of the pair of floating gates and cover a top face of each of the pair of floating gates;
an inter-gate dielectric layer disposed between the control gate and each of the floating gates, between the control gate and each of the tunneling dielectric layers, and disposed between the control gate and the substrate; and
a source/drain region disposed in the substrate at respective sides of the gate structure.

11. The non-volatile memory of claim 10, wherein the control gate completely covers each of the floating gates.

12. The non-volatile memory of claim 10, wherein a material of the pair of the floating gates comprises polysilicon.

13. The non-volatile memory of claim 10, wherein a material of the control gate comprises polysilicon.

14. The non-volatile memory of claim 10, wherein a material of the tunneling dielectric layers comprises oxide.

15. The non-volatile memory of claim 10, wherein a material of inter-gate dielectric layer comprises oxide/nitride/oxide.
